(19) United States
(12) Patent Application Publication
(10) Pub. No.: US 2026/0269099 A1
(43) Pub. Date: Sep. 10, 2026

(54) LIGHT SOURCE APPARATUS AND CONTROL METHOD OF LIGHT SOURCE APPARATUS

(71) Applicant: Lasertec Corporation, Yokohama (JP)

(72) Inventors: Masaki INOUE, Yokohama (JP); Masayasu NISHIZAWA, Yokohama (JP); Takahide TAKAMATSU, Yokohama (JP)

(21) Appl. No.: 19/559,365

(22) Filed: Mar. 6, 2026

(30) Foreign Application Priority Data
Mar. 10, 2025 (JP) 2025-037061

(51) Int. Cl. G21K 5/08

(52) U.S. Cl. CPC G21K 5/08

(57) ABSTRACT

A light source apparatus according to the present disclosure includes: a rotary body which includes a target holding unit configured to hold a target material that serves as a plasma source configured to generate plasma and a shaft portion connected to the target holding unit and which rotates around a rotational axis that passes through the shaft portion; a shaft support portion which includes a magnetic force generating unit configured to apply a magnetic force to the shaft portion and which is configured to support the shaft portion; and a control unit configured to control the magnetic force generating unit, in which the shaft support portion is configured to rotatably support the shaft portion in a state where the shaft portion is levitated by the magnetic force via the magnetic force generating unit.

### INCORPORATION BY REFERENCE

This application is based upon and claims the benefit of priority from Japanese Patent Application No. 2025-037061, filed on Mar. 10, 2025, the disclosure of which is incorporated herein in its entirety by reference for all purposes.

### BACKGROUND

The present disclosure relates to a light source apparatus and to a control method of a light source apparatus.

Patent Literature 1 describes a light source which forms a target material on a surface of a cylindrical member rotating around a rotational axis and which emits illumination light by irradiating the formed target material with excitation light.

Patent Literature 2 describes a light source which centrifugally holds a target material of molten metal on an inner wall of a crucible rotating around a rotational axis and which emits illumination light by irradiating the held target material with excitation light.

[Patent Literature 1] Japanese Unexamined Patent Application Publication No. 2020-077007

[Patent Literature 2] Japanese Unexamined Patent Application Publication No. 2022-168463

### SUMMARY

In light source apparatuses, relative positions of a light-emitting point located near a surface of a target material and optical members may vary due to vibrations generated during rotation of a target holding unit such as a cylindrical member or a crucible, deformation of the structure itself, rotational stress and thermal deformation of the target holding unit itself, the introduction of the target material into the target holding unit, and the like. In addition, the target holding unit may interfere with peripheral members. For these reasons, it is possible that light cannot be stably extracted from a light source apparatus. Therefore, appropriate control of the position of the target holding unit is desired to enable relative positions of the light-emitting point and the optical member to be readily adjusted and to prevent interference between the target holding unit and the peripheral members.

The present disclosure has been made in order to solve such a problem and an object thereof is to provide a light source apparatus and a control method of a light source apparatus that enable the position of a target holding unit to be appropriately controlled.

A light source apparatus according to the present disclosure includes: a rotary body which includes a target holding unit configured to hold a target material that serves as a plasma source configured to generate plasma and a shaft portion connected to the target holding unit and which rotates around a rotational axis that passes through the shaft portion; a shaft support portion which includes a magnetic force generating unit configured to apply a magnetic force to the shaft portion and which is configured to support the shaft portion; and a control unit configured to control the magnetic force generating unit, in which the shaft support portion is configured to rotatably support the shaft portion in a state where the shaft portion is levitated by the magnetic force via the magnetic force generating unit, and the control unit is configured to displace the shaft portion by controlling the magnetic force generating unit.

In the light source apparatus described above, the magnetic force generating unit may include a first magnetic force generating unit configured to apply the magnetic force to the shaft portion, and the control unit may be configured to displace the shaft portion in a first displacement direction including a component perpendicular to the rotation axis by controlling the first magnetic force generating unit.

In the light source apparatus described above, the rotary body may further include a disk portion which is connected to the shaft portion and which has a diameter that differs from a diameter of the shaft portion, the magnetic force generating unit may include a second magnetic force generating unit configured to apply the magnetic force to the disk portion, and the control unit may be configured to displace the shaft portion in a second displacement direction including a component parallel to the rotation axis by controlling the second magnetic force generating unit.

In the light source apparatus described above, when the target material generates plasma, the control unit may be configured to rotate the rotary body at a target rotational speed and displace the shaft portion in the first displacement direction in a state where the shaft portion is rotating at the target rotational speed by controlling the first magnetic force generating unit.

The light source apparatus described above may further include an acquiring unit configured to acquire a state of a holding surface for holding the target material in the target holding unit, and the control unit may be configured to displace the shaft portion in the first displacement direction based on an acquisition result of the state of the holding surface by the acquiring unit.

In the light source apparatus described above, the state of the holding surface may include at least one of: an amount of the target material held by the holding surface; a surface position of the target material; a surface roughness of the target material; and a surface roughness of the holding surface.

The light source apparatus described above may further include: an input optical system which has a first focusing point that is a focusing point on a side of the target material of a first optical member configured to focus excitation light onto the target material and which is configured to irradiate the target material with the excitation light; and an output optical system which has a second focusing point that is a focusing point on a side of the target material of a second optical member configured to focus light generated from the plasma source and which is configured to extract the light generated from the plasma source, in which the acquiring unit is configured to acquire a displacement of a surface position of the target material, and the control unit may be configured to displace, when the surface position is displaced, the shaft portion so that relative positions of the surface position of the target material at an irradiation position of the excitation light and at least one of the first focusing point and the second focusing point become approximately constant before and after the displacement of the surface position.

In the light source apparatus described above, the target holding unit may include a cylindrical portion and a bottom portion configured to close one of the opening portions of the cylindrical portion, the light source apparatus may further include a shield configured to close the other opening portion of the cylindrical portion, in which the control unit may be configured to displace the shaft portion in the second displacement direction by controlling the second magnetic force generating unit so that a distance between the shield and the cylindrical portion equals a predetermined target amount.

In the light source apparatus described above, the control unit may be configured to displace the shaft portion in the second displacement direction so that the distance increases when the control unit detects that predetermined conditions are fulfilled, and the predetermined conditions may include at least one of detection of a vibration of the rotary body that is greater than a predetermined vibration and detection of a rotational speed of the rotary body that is lower than a predetermined rotational speed.

In the light source apparatus described above, the control unit may be configured to acquire the surface position of the target material at the irradiation position based on a state of the holding surface which is acquired by the acquiring unit and which corresponds to a position that differs from the irradiation position.

In the light source apparatus described above, the control unit may be configured to displace the shaft portion in the first displacement direction when the surface position is displaced in a direction of increase of the target material by a predetermined amount.

A control method of a light source apparatus according to the present disclosure is a control method of a light source apparatus, the light source apparatus including: a rotary body which includes a target holding unit for holding a target material that serves as a plasma source for generating plasma and a shaft portion connected to the target holding unit and which rotates around a rotational axis that passes through the shaft portion; a shaft support portion which includes a magnetic force generating unit for applying a magnetic force to the shaft portion and which supports the shaft portion; and a control unit that controls the magnetic force generating unit, the control method including the steps of: the shaft support portion rotatably supporting the shaft portion in a state where the shaft portion is levitated by the magnetic force via the magnetic force generating unit; and the control unit displacing the shaft portion by controlling the magnetic force generating unit.

In the control method of a light source apparatus described above, the magnetic force generating unit may include a first magnetic force generating unit that applies the magnetic force to the shaft portion, and in the step of displacing the shaft portion, the control unit may displace the shaft portion in a first displacement direction including a component perpendicular to the rotation axis by controlling the first magnetic force generating unit.

In the control method of a light source apparatus described above, the rotary body may further include a disk portion which is connected to the shaft portion and which has a diameter that differs from a diameter of the shaft portion, the magnetic force generating unit may include a second magnetic force generating unit that applies the magnetic force to the disk portion, and in the step of displacing the shaft portion, the control unit may displace the shaft portion in a second displacement direction including a component parallel to the rotation axis by controlling the second magnetic force generating unit.

In the control method of a light source apparatus described above, in the step of rotatably supporting the shaft portion, when the target material generates plasma, the control unit may rotate the rotary body at a target rotational speed, and in the step of displacing the shaft portion, the control unit may displace the shaft portion in the first displacement direction in a state where the shaft portion is rotating at the target rotational speed by controlling the first magnetic force generating unit.

The control method of a light source apparatus described above may further include a step of causing an acquiring unit to acquire a state of a holding surface for holding the target material in the target holding unit, and in the step of displacing the shaft portion, the control unit may displace the shaft portion in the first displacement direction based on an acquisition result of the state of the holding surface by the acquiring unit.

In the control method of a light source apparatus described above, the state of the holding surface may include at least one of: an amount of the target material held by the holding surface; a surface position of the target material; a surface roughness of the target material; and a surface roughness of the holding surface.

In the control method of a light source apparatus described above, the light source apparatus may further include: an input optical system which has a first focusing point that is a focusing point on a side of the target material of a first optical member that focuses excitation light onto the target material and which irradiates the target material with the excitation light; and an output optical system which has a second focusing point that is a focusing point on a side of the target material of a second optical member that focuses light generated from the plasma source and which extracts the light generated from the plasma source, in which in the step of causing the acquiring unit to acquire a state of a holding surface, the acquiring unit acquires a displacement of a surface position of the target material, and in the step of displacing the shaft portion, the control unit may displace, when the surface position is displaced, the shaft portion so that relative positions of the surface position of the target material at an irradiation position of the excitation light and at least one of the first focusing point and the second focusing point become approximately constant before and after the displacement of the surface position.

In the control method of a light source apparatus described above, the target holding unit may include a cylindrical portion and a bottom portion that closes one of the opening portions of the cylindrical portion, the light source apparatus may further include a shield that closes the other opening portion of the cylindrical portion, in which in at least one of the step of rotatably supporting the shaft portion and the step of displacing the shaft portion, the control unit may displace the shaft portion in the second displacement direction by controlling the second magnetic force generating unit so that a distance between the shield and the cylindrical portion equals a predetermined target amount.

In the control method of a light source apparatus described above, in at least one of the step of rotatably supporting the shaft portion and the step of displacing the shaft portion, the control unit may displace the shaft portion in the second displacement direction so that the distance increases when the control unit detects that predetermined conditions are fulfilled, and the predetermined conditions may include at least one of detection of a vibration of the rotary body that is greater than a predetermined vibration and detection of a rotational speed of the rotary body that is lower than a predetermined rotational speed.

In the control method of a light source apparatus described above, in the step of causing the acquiring unit to acquire a state of a holding surface, the control unit may acquire the surface position of the target material at the irradiation position based on a state of the holding surface which is acquired by the acquiring unit and which corresponds to a position that differs from the irradiation position.

In the control method of a light source apparatus described above, in the step of displacing the shaft portion, the control unit may displace the shaft portion in the first displacement direction when the surface position is displaced in a direction of increase of the target material by a predetermined amount.

According to the present disclosure, the position of the target holding unit can be appropriately controlled, thereby improving the operational stability of the light source apparatus.

The above and other objects, features and advantages of the present disclosure will become more fully understood from the detailed description given hereinbelow and the accompanying drawings.

### BRIEF DESCRIPTION OF DRAWINGS

FIG. 1 is a sectional view illustrating a light source apparatus according to a first embodiment;

FIG. 2 is a perspective view illustrating a shaft support portion in the light source apparatus according to the first embodiment;

FIG. 3 is a flowchart illustrating a control method of an optical apparatus according to the first embodiment;

FIG. 4 is a sectional view illustrating an optical apparatus according to a second embodiment;

FIG. 5 is a plan view illustrating a target holding unit in a light source apparatus according to the second embodiment;

FIG. 6 is a flowchart illustrating a control method of the light source apparatus according to the second embodiment;

FIG. 7 is a sectional view illustrating a light source apparatus according to a third embodiment;

FIG. 8 is a graph illustrating an amount of whirling from a rotational axis when a rotary body rotates around the rotational axis in a light source apparatus according to the fourth embodiment, in which the horizontal axis indicates a frequency of rotation of the rotary body and the vertical axis indicates the amount of whirling; and

FIG. 9 is a configuration diagram illustrating an inspection apparatus including a light source apparatus according to a fifth embodiment.

### DESCRIPTION OF EMBODIMENTS

Hereinafter, specific configurations of present embodiments will be described with reference to the drawings. The following description is intended as a description of embodiments of the present disclosure and is not intended to limit the scope of the present disclosure to the following embodiments. In the following description, same reference signs denote substantially similar contents. Reference signs and hatchings of some elements have been omitted to avoid complicating the drawings.

### First embodiment

A light source apparatus according to a first embodiment will be described. The light source apparatus according to the present embodiment generates light such as illumination light used in optical apparatuses such as an inspection apparatus and a review apparatus, exposure light used in optical apparatuses such as an exposure apparatus, and the like. The light source apparatus may be integrally provided with the optical apparatus or arranged in a vicinity of the optical apparatus as a separate body from the optical apparatus. When the optical apparatus is an inspection apparatus and a review apparatus, the light source apparatus generates illumination light that illuminates an object. In addition, when the optical apparatus is an exposure apparatus, the light source apparatus generates exposure light that exposes an object.

The light source apparatus generates light such as illumination light or exposure light by irradiating a target material held by a target holding unit with excitation light. Hereinafter, an example of using a molten substance held in a container as a target material will be described as an example of the light source apparatus. Note that the light source apparatus is not limited to using a molten substance held in a container as the target material and may use a molten substance with a droplet shape, a solid substance fixed to a cylinder-shaped drum, or the like as the target material.

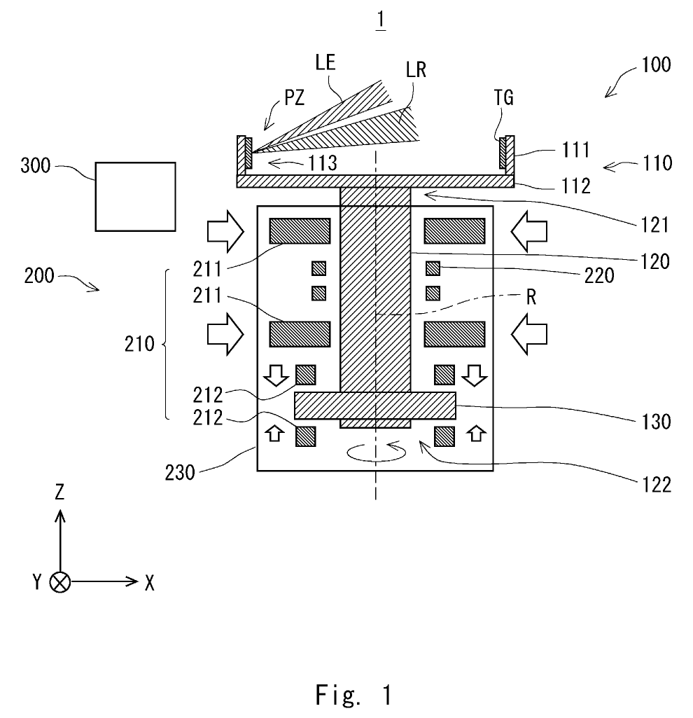

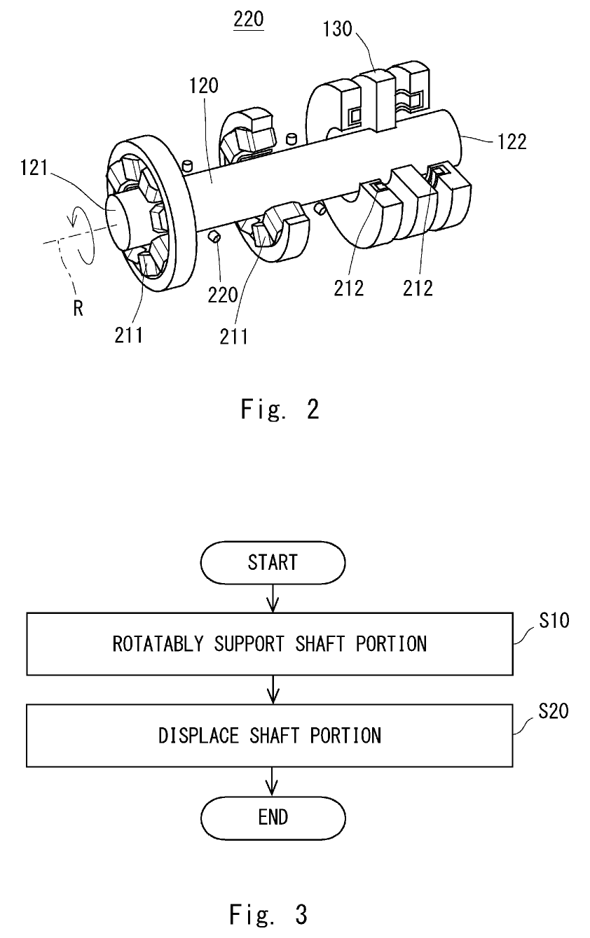

FIG. 1 is a sectional view illustrating a light source apparatus 1 according to the first embodiment. FIG. 2 is a perspective view illustrating a shaft support portion 200 in the light source apparatus 1 according to the first embodiment. FIG. 2 shows a cross section of a part of the shaft support portion 200. As shown in FIGS. 1 and 2, the light source apparatus 1 includes a rotary body 100, the shaft support portion 200, and a control unit 300. Hereinafter, the respective members will be described in <Rotary Body>, <Shaft Support Portion>, and <Control Unit>.

### Rotary Body

The rotary body 100 rotates around a rotational axis R. Here, an XYZ orthogonal coordinate axes system with the rotational axis R as a Z-axis direction will be introduced for convenience of description of the light source apparatus 1. For example, a +Z-axis direction may be referred to as upward and a -Z-axis direction may be referred to as downward. Note that upward and downward are directions for convenience of description and are not intended to limit orientations of the respective members.

The rotary body 100 includes a target holding unit 110 and a shaft portion 120. The target holding unit 110 holds a target material TG to serve as a plasma source that generates plasma PZ. In the present embodiment, as one example, the target holding unit 110 includes a container such as a crucible. As one example, the target material TG contains a molten substance such as molten tin (Sn) or molten lithium (Li). Note that the target holding unit 110 is not limited to a container and may be a cylindrical (cylinder-shaped) drum. In such a case, the target holding unit 110 may hold the target material TG by fixing a solid substance such as frozen xenon (Xe) to a surface of the drum.

The target holding unit 110 includes a cylindrical portion 111 and a bottom portion 112. For example, the cylindrical portion 111 may be a cylindrical shape having a central axis that extends in the Z-axis direction. The central axis of the cylindrical portion 111 may coincide with the rotational axis R. The cylindrical portion 111 has opening portions on a +Z-axis direction side and a -Z-axis direction side. The cylindrical portion 111 may hold the target material TG on an inner circumferential surface. In this case, a holding surface 113 that holds the target material TG includes the inner circumferential surface of the cylindrical portion 111. The target material TG may be held on the holding surface 113 by a centrifugal force generated as the rotary body 100 rotates about the rotational axis R.

The holding surface 113 formed so as to surround the rotational axis R may include a cylindrical portion where a distance from an upper end to a lower end relative to the rotational axis R is constant or may have a barrel-shape with a bulging intermediate portion between the upper and lower ends. In addition, the holding surface 113 may include a bowl-shaped portion that widens outward toward the top. The holding surface 113 may be formed in a groove formed in an annular shape along the inner circumferential surface of the cylindrical portion 111.

For example, the bottom portion 112 may be a disk shape having a central axis that extends in the Z-axis direction. The central axis of the bottom portion 112 may coincide with the rotational axis R. The bottom portion 112 blocks the opening portion on the -Z-axis direction side of the cylindrical portion 111. Accordingly, the target holding unit 110 has a container shape with the +Z-axis direction side of the cylindrical portion 111 opened. Note that the holding surface 113 may include an inner surface on the +Z-axis direction side of the bottom portion 112.

The target holding unit 110 may include a heater (not illustrated) that melts the target material TG.

The shaft portion 120 is connected to the target holding unit 110. The shaft portion 120 is a rod shape that extends in the Z-axis direction. The rotational axis R passes though the shaft portion 120. For example, the rotational axis R may coincide with a central axis of the shaft portion 120. Therefore, the rotary body 100 rotates around the rotational axis R that passes through the shaft portion 120.

The shaft portion 120 contains a material that adheres to magnets or electromagnets. For example, the shaft portion 120 may contain at least one ferromagnetic material among iron, cobalt, and nickel. The shaft portion 120 is not limited to a material containing iron, cobalt, nickel, or other metals, as long as it contains a material that adheres to magnets or electromagnets or, in other words, a magnetic body. The shaft portion 120 may contain a magnet or an electromagnet.

The shaft portion 120 has an end portion 121 on a +Z-axis direction side and an end portion 122 on a -Z-axis direction side. The end portion of the shaft portion 120 on the +Z-axis direction side is connected to the target holding unit 110. Specifically, the end portion of the shaft portion 120 on the +Z-axis direction side is connected to a surface of the bottom portion 112 on the -Z-axis direction side. The shaft portion 120 may penetrate the bottom portion 112 or, in other words, the end portion of the shaft portion 120 on the +Z-axis direction side may be on a positive side in the Z-axis direction relative to the bottom portion 112. The shaft portion 120 has a side surface facing a direction orthogonal to the rotational axis R.

The rotary body 100 may further include a disk portion 130. For example, the disk portion 130 may be an annular shape having a central axis that extends in the Z-axis direction. For example, the disk portion 130 may be a polygonal shape having a central axis that extends in the Z-axis direction. The central axis of the disk portion 130 may coincide with the rotational axis R. The disk portion 130 has a diameter that differs from a diameter of the shaft portion 120. Specifically, the diameter centered on the rotational axis R of the disk portion 130 is larger than the diameter centered on the rotational axis R of the shaft portion 120. The disk portion 130 is connected to the shaft portion 120. For example, the disk portion 130 is connected to the shaft portion 120 by fitting the shaft portion 120 into a central hole of the annular disk portion 130. The disk portion 130 has an annular top surface and an annular bottom surface in a plane perpendicular to the rotational axis R.

### Shaft Support Portion

The shaft support portion 200 supports the shaft portion 120. The shaft support portion 200 includes a magnetic force generating unit 210. The magnetic force generating unit 210 imparts a magnetic force to the shaft portion 120. The shaft support portion 200 can place the shaft portion 120 in a levitated state due to the magnetic force via the magnetic force generating unit 210. The shaft support portion 200 rotatably supports the shaft portion 120 in a state where the shaft portion 120 is levitated by the magnetic force. The shaft support portion 200 may include an enclosure 230. The magnetic force generating unit 210 and the shaft portion 120 may be arranged inside the enclosure 230.

The magnetic force generating unit 210 may include a first magnetic force generating unit 211 and a second magnetic force generating unit 212. Note that the magnetic force generating unit 210 may include the first magnetic force generating unit 211 and may not include the second magnetic force generating unit 212. Alternatively, the magnetic force generating unit 210 may include the second magnetic force generating unit 212 and may not include the first magnetic force generating unit 211.

The first magnetic force generating unit 211 imparts a magnetic force to the shaft portion 120. For example, the first magnetic force generating unit 211 includes an electromagnet. The first magnetic force generating unit 211 may be arranged so as to surround a part of the side surface of the shaft portion 120. According to such a configuration, the first magnetic force generating unit 211 imparts a magnetic force to the shaft portion 120. The first magnetic force generating unit 211 may be arranged at a distance from a part of the side surface of the shaft portion 120.

The first magnetic force generating unit 211 may impart, to the shaft portion 120, a magnetic force that causes the shaft portion 120 to rotate around the rotational axis R. In addition, the first magnetic force generating unit 211 may impart, to the shaft portion 120, a magnetic force that causes the shaft portion 120 to be displaced in a first displacement direction including a component that is perpendicular to the rotational axis R. The first displacement direction may include a direction parallel to the XY plane.

The second magnetic force generating unit 212 imparts a magnetic force to the disk portion 130. For example, the second magnetic force generating unit 212 includes an electromagnet. The second magnetic force generating unit 212 may be arranged so as to oppose a surface on the +Z-axis direction side and a surface on the-Z-axis direction side of the disk portion 130. For example, the disk portion 130 is arranged between the second magnetic force generating unit 212 arranged on the +Z-axis direction side of the disk portion 130 and the second magnetic force generating unit 212 arranged on the -Z-axis direction side of the disk portion 130. According to such a configuration, the second magnetic force generating unit 212 imparts a magnetic force to the disk portion 130. The second magnetic force generating unit 212 may be arranged at a distance from the surface on the +Z-axis direction side and the surface on the-Z-axis direction side of the disk portion 130.

The second magnetic force generating unit 212 may impart, to the shaft portion 120, a magnetic force that causes the shaft portion 120 to rotate around the rotational axis R. In addition, the second magnetic force generating unit 212 may impart, to the shaft portion 120, a magnetic force that causes the shaft portion 120 to be displaced in a second displacement direction including a component that is parallel to the rotational axis R. The second displacement direction may include a direction parallel to the Z-axis.

The shaft support portion 200 may include a plurality of sensors 220. The shaft support portion 200 may include a sensor 220 that detects a position of the shaft portion 120. In addition, the shaft support portion 200 may include a sensor 220 that detects the number of revolutions of the shaft portion 120. The shaft support portion 200 may include various other types of sensors 220 that detect a temperature or the like.

The first magnetic force generating unit 211 and the second magnetic force generating unit 212 in the magnetic force generating unit 210 are connected to the control unit 300 in a state of being capable of transmitting information. The first magnetic force generating unit 211 and the second magnetic force generating unit 212 generate a magnetic force under the control of the control unit 300. The sensors 220 are connected to the control unit 300 in a state of being capable of transmitting information. The sensors 220 output detection results such as a detected position of the shaft portion 120, the detected number of revolutions of the shaft portion 120, and the detected temperature of the shaft portion 120 to the control unit 300.

### Control Unit

The control unit 300 controls the magnetic force generating unit 210. For example, the control unit 300 controls the magnetic force generating unit 210 by controlling a current that flows through an electromagnet included in the magnetic force generating unit 210. The control unit 300 rotates the shaft portion 120 around the rotational axis R by controlling the magnetic force generating unit 210. Accordingly, the control unit 300 rotates the rotary body 100 around the rotational axis R. The control unit 300 displaces the shaft portion 120 by controlling the magnetic force generating unit 210. Accordingly, the control unit 300 moves the position of the rotary body 100.

Specifically, the control unit 300 displaces the shaft portion 120 in the first displacement direction including a component that is perpendicular to the rotational axis R by controlling the first magnetic force generating unit 211. Accordingly, the control unit 300 moves the position of the rotary body 100 in the first displacement direction including a component that is perpendicular to the rotational axis R. In addition, the control unit 300 displaces the shaft portion 120 in the second displacement direction including a component that is parallel to the rotational axis R by controlling the second magnetic force generating unit 212. Accordingly, the control unit 300 moves the position of the rotary body 100 in the second displacement direction including a component that is parallel to the rotational axis R.

When generating the plasma PZ on the target material TG by irradiating the target material TG with excitation light LR, the control unit 300 rotates the rotary body 100 at a target rotational speed. In this case, the control unit 300 displaces the shaft portion 120 in the first displacement direction in a state where the shaft portion 120 is rotating at the target rotational speed by controlling the first magnetic force generating unit 211. Accordingly, when a surface position of the target material TG relative to a focusing point of the excitation light LR is displaced by, for example, a return current of the target material TG, the surface position of the target material TG can be corrected. Therefore, the light source apparatus 1 can be operated continuously while stably extracting light.

The return current of the target material TG refers to the target material TG having scattered from the target holding unit 110 returning back to the target holding unit 110. Note that the control unit 300 does not preclude displacing the shaft portion 120 in the first displacement direction in a state where the shaft portion 120 is not rotating at the target rotational speed. The state where the shaft portion 120 is not rotating at the target rotational speed includes a state where the rotation of the shaft portion 120 has stopped.

On the other hand, the control unit 300 may displace the shaft portion 120 in the second displacement direction in a state where the shaft portion 120 is not rotating at the target rotational speed by controlling the second magnetic force generating unit 212. Accordingly, the position of the rotary body 100 can be lowered at start and stop of rotation of the rotary body 100 and a clearance margin can be secured with other members such as a debris shield to be described later. Therefore, interference with other members can be suppressed. By controlling the second magnetic force generating unit 212, the control unit 300 may displace the shaft portion 120 in the second displacement direction in a state where the shaft portion 120 is rotating at the target rotational speed. Specifically, the control unit 300 may displace the shaft portion 120 to an extent that interference does not occur in a state where the shaft portion 120 is rotating at the target rotational speed.

### Control Method of Light Source Apparatus

FIG. 3 is a flowchart illustrating a control method of the light source apparatus 1 according to the first embodiment. As shown in FIG. 3, the control method of the light source apparatus 1 includes step S10 of rotatably supporting the shaft portion 120 and step S20 of displacing the shaft portion 120.

In step S10, the shaft support portion 200 rotatably supports the shaft portion 120 in a state where the shaft portion 120 is levitated by a magnetic force via the magnetic force generating unit 210.

In step S20, the control unit 300 displaces the shaft portion 120 by controlling the magnetic force generating unit 210. In step S20, the control unit 300 may displace the shaft portion 120 in the first displacement direction including a component that is perpendicular to the rotational axis R by controlling the first magnetic force generating unit 211. In addition, the control unit 300 may displace the shaft portion 120 in the second displacement direction including a component that is parallel to the rotational axis R by controlling the second magnetic force generating unit 212.

In step S10, when the target material TG generates the plasma PZ, the control unit 300 may rotate the rotary body 100 at the target rotational speed. In this case, in step S20, the control unit 300 may displace the shaft portion 120 in the first displacement direction in a state where the shaft portion 120 is rotating at the target rotational speed by controlling the first magnetic force generating unit 211.

Next, an advantageous effect of the present embodiment will be described. The light source apparatus 1 according to the present embodiment can control the position of the rotating rotary body 100 by a magnetic force by using the shaft support portion 200 that supports the shaft portion 120 being levitated by the magnetic force. Specifically, the shaft portion 120 of the rotary body 100 can be rotatably supported in a state where the shaft portion 120 is levitated by a magnetic force via the magnetic force generating unit 210. The control unit 300 displaces the shaft portion 120 by controlling the magnetic force generating unit 210. Therefore, the position of a light-emitting point and a light extraction intensity of the plasma PZ in the light source apparatus 1 can be appropriately adjusted. In addition, the clearance between the rotary body 100 and the peripheral members can be adjusted as desired. In this manner, since the position of the rotary body 100 can be appropriately controlled, stability of light LE extracted from the light source apparatus 1 can be improved and a stable operation that avoids interference with peripheral members can be realized.

The magnetic force generating unit 210 includes the first magnetic force generating unit 211 that displaces the shaft portion 120 in the first displacement direction including a component that is perpendicular to the rotational axis R and the second magnetic force generating unit 212 that displaces the shaft portion 120 in the second displacement direction including a component that is parallel to the rotational axis R. Accordingly, the light source apparatus 1 can move the position of the rotating rotary body 100 to any position in the XYZ-axis directions. As a result, the position to which the rotary body 100 is displaced can be determined with high accuracy.

The control unit 300 can displace the shaft portion 120 in the first displacement direction and the second displacement direction in a state where the shaft portion 120 is rotating at the target rotational speed. Therefore, the light source apparatus 1 can be operated without having to stop the rotation of the rotary body 100.

### Second Embodiment

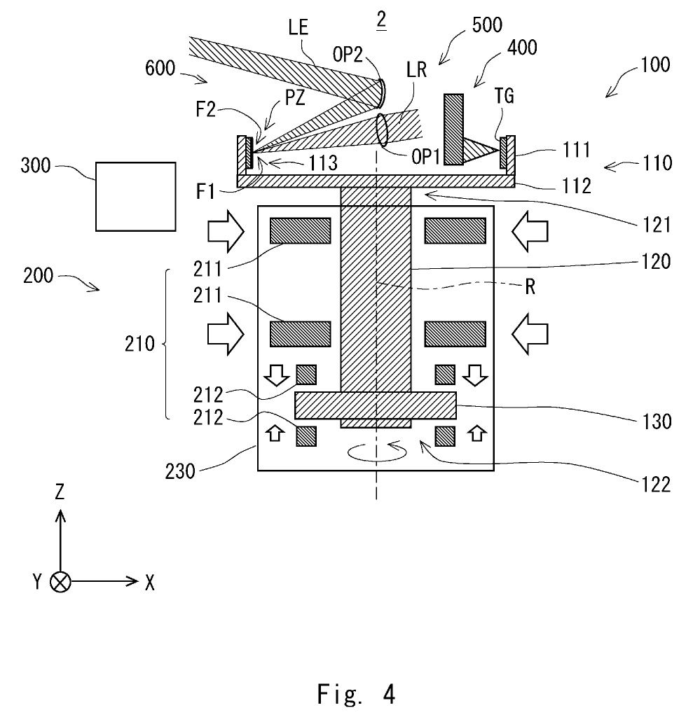

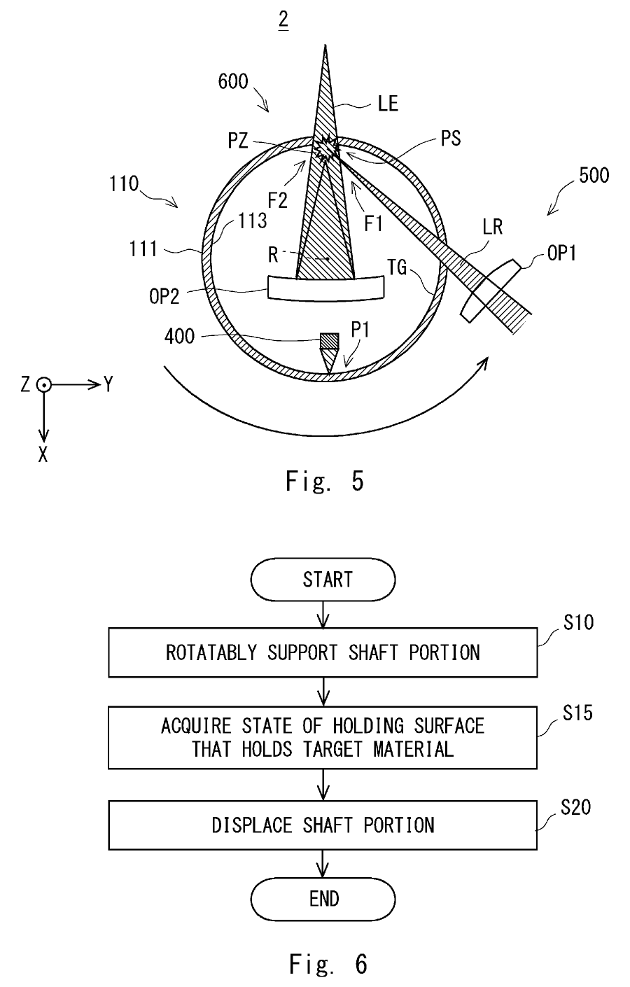

Next, a second embodiment will be described. In the present embodiment, a state of the holding surface 113 of the target holding unit 110 is acquired by an acquiring unit 400. This also serves as an example corresponding to the return current of the target material TG and the consumption of the target material TG. FIG. 4 is a sectional view illustrating a light source apparatus 2 according to the second embodiment. FIG. 5 is a plan view illustrating the target holding unit 110 in the light source apparatus 2 according to the second embodiment. As shown in FIGS. 4 and 5, in addition to the rotary body 100, the shaft support portion 200, and the control unit 300, the light source apparatus 2 further includes the acquiring unit 400.

The acquiring unit 400 acquires the state of the holding surface 113 that holds the target material TG in the target holding unit 110. The state of the holding surface 113 includes at least one of: an amount of the target material TG held by the holding surface 113; a surface position of the target material TG; and a displacement of the surface position of the target material TG. The state of the holding surface 113 may include at least one of: a surface roughness of the target material TG; and a surface roughness of the holding surface 113.

The acquiring unit 400 may include at least one of a displacement meter, a high-speed camera, a low-speed camera, a quadrant PD (photodiode), and a TDI (Time Delay Integration) camera. In addition, the acquiring unit 400 may measure the state of the holding surface 113 in one dimension, two dimensions, three dimensions, or any combination thereof.

The acquiring unit 400 is connected to the control unit 300 in a state of being capable of transmitting information. The acquiring unit 400 outputs information on the acquired state of the holding surface 113 to the control unit 300.

The control unit 300 displaces the shaft portion 120 based on an acquisition result of the state of the holding surface 113 by the acquiring unit 400. For example, the control unit 300 displaces the shaft portion 120 in the first displacement direction based on an acquisition result of the state of the holding surface 113 by the acquiring unit 400. For example, when a surface position of the target material TG on an inner circumferential surface of the cylindrical portion 111 as the holding surface 113 is displaced due to a return current or consumption of the target material TG, the control unit 300 displaces the shaft portion 120 in the first displacement direction. Note that the control unit 300 may displace the shaft portion 120 in the second displacement direction based on an acquisition result of the state of the holding surface 113 by the acquiring unit 400. When a return current of the target material TG occurs, the surface position of the target material TG is displaced so as to approach the rotational axis R. In addition, when consumption of the target material TG occurs, the surface position of the target material TG is displaced so as to move away from the rotational axis R. The control unit 300 may displace the shaft portion 120 in the first displacement direction when a displacement equal to or greater than a predetermined displacement is acquired based on the surface position of the target material TG by the acquiring unit 400.

The light source apparatus 1 further includes an input optical system 500 and an output optical system 600. The input optical system 500 irradiates the target material TG with the excitation light LR. The input optical system 500 includes an optical member OP1 that focuses the excitation light LR onto the target material TG. For example, the optical member OP1 includes a focusing lens. Note that the optical member OP1 may be a mirror or the like as long as the optical member OP1 is capable of focusing the excitation light LR onto the target material TG. The input optical system 500 includes a focusing point F1 on the side of the target material TG of the optical member OP1.

The optical member OP1 may irradiate the target material TG with the excitation light LR at an angle that is inclined with respect to a perpendicular axis to a surface of the target material TG. Specifically, for example, the optical member OP1 emits the excitation light LR at an angle of incidence that is inclined with respect to a surface of an irradiation position PS that is irradiated with the excitation light LR.

The input optical system 500 may include a laser apparatus that generates the excitation light LR. Note that the input optical system 500 may guide the excitation light LR generated by a laser apparatus separate from the light source apparatus 2 to the light source apparatus 2.

The output optical system 600 extracts light LE generated from the plasma PZ from the light source apparatus 1. The output optical system 600 includes an optical member OP2 that focuses the light LE generated from a plasma source. For example, the optical member OP2 includes a collector mirror such as an ellipsoidal mirror. Note that the optical member OP2 may be a focusing lens or the like as long as the optical member OP2 is capable of focusing the light LE generated from the plasma PZ. In addition, the optical member OP2 may be a second collector mirror that further reflects the light LE having been reflected by the collector mirror. The output optical system 600 includes a focusing point F2 on the side of the target material TG of the optical member OP2.

On a plane including the rotational axis R, a position where a plane including a focusing point F1 that is a reference position of the focusing point F1 intersects with the inner circumferential surface of the cylindrical portion 111 will be referred to as an irradiation position PS (an irradiation position of the target material TG with the excitation light LR). FIG. 4 is a sectional view of the light source apparatus 2 taken along a plane including the irradiation position PS and the rotational axis R. In FIG. 4, a surface position (bold line in FIG. 4) of the target material TG at the irradiation position PS coincides with the positions of the focusing points F1 and F2.

Here, the surface position of the target material TG at the irradiation position PS varies due to variations in the amount of the target material TG in the rotary body 100 caused by a return current or consumption of the target material TG. Specifically, due to an increase in the amount of the target material TG in the rotary body 100, a surface position of the target material TG at the irradiation position PS varies so as to approach the rotational axis R. In addition, due to a decrease in the amount of the target material TG in the rotary body 100, the surface position of the target material TG at the irradiation position PS varies so as to move away from the rotational axis R. Due to variations in the surface position of the target material TG, relative positions of the surface position of the target material TG at the irradiation position PS and the focusing points F1 and F2 may vary. A change in relative positions causes defocusing of the optical members OP1 and OP2 with respect to the target material TG and may cause variations in a size and a position of the plasma PZ, variations in intensity of the extracted light LE, and the like. In this manner, a change in relative positions impairs the stability of the light LE extracted from the light source apparatus 1. Accordingly, the control unit 300 varies the position of the rotary body 100 as follows.

When the surface position of the target material TG is displaced, the control unit 300 displaces the shaft portion 120 so that the relative positions of the surface position of the target material TG at the irradiation position PS and at least one of the focusing points F1 and F2 are approximately constant before and after the displacement of the surface position. For example, when the surface position of the target material TG is displaced by a predetermined amount in a direction of increase of the target material TG due to a return current of the target material TG, the control unit 300 displaces the shaft portion 120 in the first displacement direction. In addition, the control unit 300 may displace the shaft portion 120 in the first displacement direction when the surface position of the target material TG is displaced by a predetermined amount in a direction of decrease of the target material TG due to consumption of the target material TG. Note that when the surface position of the target material TG is displaced by a predetermined amount in a direction of increase (direction of decrease) of the target material TG due to a return current (consumption) of the target material TG, the control unit 300 may displace the shaft portion 120 in the second displacement direction.

When the surface position of the target material TG is predicted to be displaced by a predetermined amount in the direction of increase of the target material TG, the control unit 300 may displace the shaft portion 120 in at least one of the first displacement direction and the second displacement direction.

The acquiring unit 400 may measure and acquire the surface position of the target material TG at the irradiation position. In this case, the control unit 300 acquires a displacement of the surface position of the target material TG at the irradiation position PS. However, arranging the acquiring unit 400 near the irradiation position PS to enable the surface position of the target material TG at the irradiation position PS to be measured and acquired risks exposing the acquiring unit 400 to debris or thermal effects.

In consideration thereof, the acquiring unit 400 is desirably arranged so as to oppose a peripheral position at a distance from the irradiation position PS. The peripheral position includes portions other than the irradiation position PS on the holding surface 113 of the target holding unit 110. For example, the acquiring unit 400 may be arranged so as to oppose a position P1 on an opposite side to the irradiation position PS relative to the rotational axis R. Accordingly, debris or thermal effects can be suppressed. Note that the acquiring unit 400 is not limited to being arranged at the position P1 and may be arranged so as to oppose a peripheral position other than the position P1 as long as debris or thermal effects can be reduced.

As described above, the acquiring unit 400 may measure and acquire the surface position at a peripheral position other than the irradiation position PS. In this case, the control unit 300 acquires a surface position of the target material TG at the irradiation position PS from a result acquired by the acquiring unit 400 of the surface position of the target material TG at a position that differs from the irradiation position PS. The control unit 300 may acquire, from the surface position of the target material TG at the peripheral position acquired by the acquiring unit 400, a displacement of the surface position of the target material TG at the peripheral position and, further, predict a displacement of the surface position of the target material TG at the irradiation position PS. In addition, the control unit 300 may predict the displacement of the surface position of the target material TG in consideration of an inclination or vibration of the target holding unit 110 relative to the rotational axis R.

For example, the acquiring unit 400 acquires the surface position of the target material TG at a position before the irradiation position PS relative to the direction of rotation of the target holding unit 110. The control unit 300 acquires the displacement of the surface position of the target material TG at a peripheral position at such a position before the irradiation position PS and predicts a displacement of the surface position of the target material TG at the irradiation position PS from the acquired displacement. In this case, by taking the rotational speed of the target holding unit 110 into consideration, the control unit 300 can predict the displacement of the surface position of the target material TG at the irradiation position PS at a time point (irradiation time point) where the excitation light LR reaches the irradiation position PS. In this manner, the control unit 300 acquires the displacement of the surface position of the target material TG at the irradiation position PS by predicting the displacement of the surface position of the target material TG at the irradiation position PS.

The acquiring unit 400 may acquire the surface position of the target material TG as a relative position with respect to the optical member OP2. In addition, the control unit 300 may acquire the displacement of the surface position of the target material TG as a displacement of the relative position with respect to the optical member OP2. Specifically, the acquiring unit 400 may measure and acquire the surface position of the target material TG at the irradiation position PS as a relative position with respect to the optical member OP2 or measure and acquire the surface position at a peripheral position as a relative position with respect to the optical member OP2. Therefore, the control unit 300 may acquire the displacement of the surface position of the target material TG at the irradiation position PS as a displacement of the relative position with respect to the optical member OP2.

The acquiring unit 400 may acquire the surface position of the target material TG based on a thickness of the molten target material TG from the holding surface 113. Therefore, the control unit 300 may acquire the displacement of the surface position of the target material TG based on the thickness of the molten target material TG from the holding surface 113. Note that when the target material TG is a solid substance fixed to a cylindrical drum, the acquiring unit 400 may acquire the surface position of the target material TG based on the thickness of a surface of the solid substance fixed to the drum from an upper surface (surface layer) of the drum as well as an inclination and an amount of vibration of the drum. The control unit 300 may acquire the displacement of the surface position of the target material TG based on the thickness of a surface of the solid substance fixed to the drum from an upper surface (surface layer) of the drum as well as an inclination and an amount of vibration of the drum. In addition, the acquiring unit 400 may acquire the surface position of the target material TG by measuring a distance from the acquiring unit 400 to the surface position of the target material TG.

The control unit 300 may acquire the displacement of the surface position of the target material TG at the irradiation position PS by combining the acquiring unit 400 with other sensors. Accordingly, a displacement of the surface position due to temperature changes in each member of the light source apparatus 2 and a displacement of the surface position due to stress changes can be compensated for by other sensors. Specifically, the control unit 300 may correct the displacement of the surface position of the target material TG based on a temperature change acquired by a temperature sensor provided in the target holding unit 110. In addition, the control unit 300 may correct the displacement of the surface position of the target material TG based on a stress change acquired by a stress sensor provided in the target holding unit 110.

In addition, the acquisition of a displacement of the surface position by the control unit 300 may include detecting that a displacement of the surface position is occurring at that time point (in other words, acquiring the fact of displacement) or calculating an amount of displacement thereof. For example, the control unit 300 may detect that the surface position of the target material TG at that time point has been displaced from the surface position of the target material TG at a time point where the target material TG had previously been irradiated with the excitation light LR or calculate an amount of displacement thereof.

In addition, the control unit 300 may detect that the surface position of the target material TG has been displaced from a reference surface position (in other words, a reference position of the surface position: for example, a position that overlaps with the focusing point F1) or calculate an amount of displacement thereof. Furthermore, the acquisition of a displacement of the surface position by the control unit 300 may include predicting an occurrence or a displacement amount of a displacement of the surface position at a future time point (for example, a time point where the excitation light LR is to be emitted). For example, the control unit 300 may predict that the surface position of the target material TG at a future time point where the target material TG is to be irradiated with the excitation light LR is to be displaced from the surface position of the target material TG at a time point where the target material TG had previously been irradiated with the excitation light LR or predict an amount of displacement thereof. In addition, the control unit 300 may predict that the surface position of the target material TG at a future time point where the target material TG is to be irradiated with the excitation light LR is to be displaced from a reference position of the surface position of the target material TG or predict an amount of displacement thereof.

FIG. 6 is a flowchart illustrating a control method of the light source apparatus 2 according to the second embodiment. As shown in FIG. 6, the control method of the light source apparatus 2 according to present embodiment further includes step S15 of acquiring a state of the holding surface 113 that holds the target material TG. Step S15 may be performed between step S10 and step S20.

In step S15, the control unit 300 causes the acquiring unit 400 to acquire the state of the holding surface 113 that holds the target material TG in the target holding unit 110. In this case, in step S20, the control unit 300 may displace the shaft portion 120 based on an acquisition result of the state of the holding surface 113 by the acquiring unit 400.

In addition, in step S15, the acquiring unit 400 may acquire a displacement of the surface position of the target material TG. In this case, in step S20, when the surface position is displaced, the control unit 300 displaces the shaft portion 120 so that the relative positions of the surface position and at least one of the focusing points F1 and F2 are approximately constant before and after the displacement of the surface position. Furthermore, the control unit 300 may displace the shaft portion 120 in the first displacement direction when the surface position of the target material TG is displaced by a predetermined amount in a direction of increase of the target material TG.

Note that in step S15, the control unit 300 may acquire the surface position PS of the target material TG at the irradiation position PS based on the state of the holding surface 113 which is acquired by the acquiring unit 400 and which corresponds to a position that differs from the irradiation position PS. The control unit 300 may acquire the surface position from a result of acquiring a position that differs from the focusing point F1 by the acquiring unit 400. For example, the control unit 300 may acquire the surface position from a result of acquiring the state of the position P1 by the acquiring unit 400.

Next, an advantageous effect of the present embodiment will be described. The light source apparatus 2 according to present embodiment includes the acquiring unit 400 that acquires a state of the holding surface 113 for holding the target material TG. Therefore, the light source apparatus 2 can displace the shaft portion 120 to an optimal position according to the state of the holding surface 113. For example, when a return current of the target material TG occurs, the acquiring unit 400 acquires a displacement of the surface position of the target material TG. In addition, the control unit 300 displaces the shaft portion 120 so as to cancel the displacement of the surface position of the target material TG due to the return current. Specifically, the control unit 300 acquires the displacement of the surface position of the target material TG at the irradiation position PS based on a detection result by the acquiring unit 400. In addition, the control unit 300 displaces the shaft portion 120 so that the relative positions of the surface position of the target material TG at the irradiation position PS and at least one of the focusing points F1 and F2 are approximately constant before and after the displacement of the surface position of the target material TG. Accordingly, focus of the optical member OP1 or the optical member OP2 on the target material TG can be suitably maintained and stability of light LE extracted from the light source apparatus 2 can be improved.

### Third Embodiment

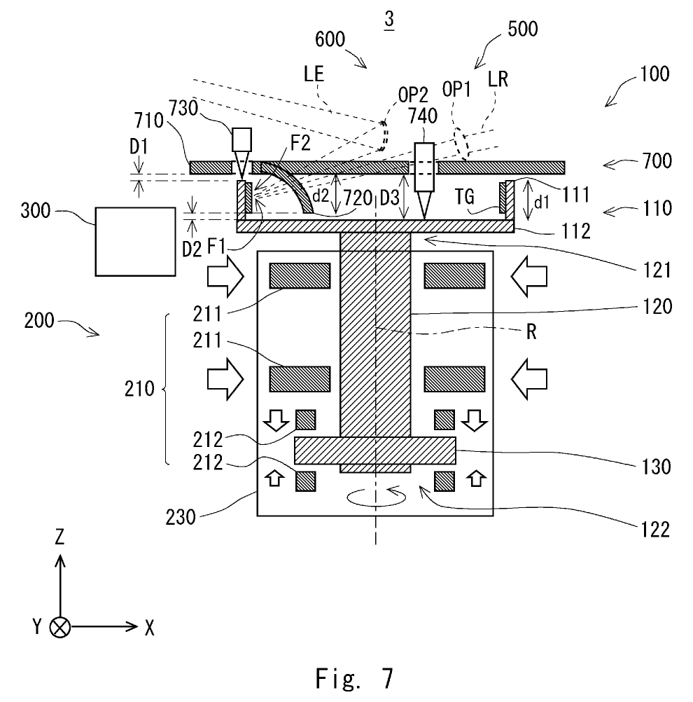

FIG. 7 is a sectional view illustrating a light source apparatus 3 according to a third embodiment. As shown in FIG. 7, the light source apparatus 3 may further include a shield 700. The shield 700 covers the opening portion on the +Z-axis direction side of the cylindrical portion 111 in the target holding unit 110. The shield 700 is, for example, a plate shape. Note that the shield 700 is not limited to a plate shape and may be a film shape as long as the shield 700 can cover the opening portion on the +Z-axis direction side of the cylindrical portion 111 in the target holding unit 110. In addition, the shield 700 may include a hole through which excitation light LR and light LE pass. In this case, the shield 700 may include a cover that covers a periphery of the hole so as to suppress scattering of debris from the hole. The shield 700 may include a debris shield 710 and a debris catcher 720.

The debris shield 710 covers the opening portion on the +Z-axis direction side of the cylindrical portion 111 in the target holding unit 110. Accordingly, scattering of debris to the outside of the light source apparatus 3 can be suppressed. In addition, the debris shield 710 may capture debris and return the debris to the target holding unit 110 as the target material TG or, in other words, create a return current.

The debris catcher 720 covers a periphery of the focusing point F1 of the excitation light LR. Since the debris catcher 720 covers the periphery of the focusing point F1 where debris is most likely to be created in the target holding unit 110, the scattering of debris can be effectively suppressed.

The control unit 300 displaces the shaft portion 120 in the second displacement direction by controlling the second magnetic force generating unit 212 so that a distance between the shield 700 and the target holding unit 110 equals a predetermined target amount. Specifically, the control unit 300 displaces the shaft portion 120 in the second displacement direction by controlling the second magnetic force generating unit 212 so that a distance D1 between the debris shield 710 (shield 700) and the cylindrical portion 111 equals a predetermined target amount. In addition, the control unit 300 displaces the shaft portion 120 in the second displacement direction by controlling the second magnetic force generating unit 212 so that a distance D2 between the debris catcher 720 and the bottom portion 112 equals a predetermined target amount. Furthermore, the control unit 300 displaces the shaft portion 120 in the second displacement direction by controlling the second magnetic force generating unit 212 so that a distance D3 between the debris shield 710 and the bottom portion 112 equals a predetermined target amount.

For example, the control unit 300 can acquire the distances D1, D2, and D3 as follows. Specifically, the control unit 300 acquires the distance D1 based on an output value of a displacement meter 730 that emits measurement light from the side of the debris shield 710 toward the cylindrical portion 111 and on a known position of the debris shield 710. In addition, the control unit 300 acquires the distance D3 based on an output value of a displacement meter 740 that emits measurement light from the side of the debris shield 710 toward the bottom portion 112 and on a known position of the debris shield 710. Note that when a height d1 of the cylindrical portion 111 is known, the control unit 300 can acquire, based on the measured value of one of the distance D1 and the distance D3 and the height d1, the other of the distance D1 and the distance D3 by calculating distance D1 + height d1 or distance D3 - height d1. In this case, the light source apparatus 3 may be provided with only one of the displacement meter 730 and the displacement meter 740. Furthermore, the control unit 300 can acquire the distance D2 from a difference between the distance D3 and a known distance d2 from the debris shield 710 to a tip of the debris catcher 720 (distance D3 - distance d2).

The control unit 300 may displace the shaft portion 120 in the second displacement direction so that the distances D1 and D2 increase when the fulfillment of predetermined conditions is detected. In addition, the control unit 300 may displace the shaft portion 120 in the second displacement direction so that the distance between the shield 700 and the target holding unit 110 increases when the fulfillment of predetermined conditions is detected. The distance between the shield 700 and the target holding unit 110 may be evaluated by at least one of the distances D1, D2, and D3. For example, the predetermined conditions include detecting at least one of the following: detecting vibration of the rotary body 100 that is greater than a predetermined value; and detecting a rotational speed of the rotary body 100 that is lower than a predetermined value. The predetermined conditions may include the temperature of the target material TG not being equal to or higher than a predetermined value. Accordingly, interference between the target holding unit 110 and peripheral members attributable to insufficient melting of the target material TG or other factors can be prevented, thereby stabilizing the operation of the light source apparatus 3. Note that the temperature of the target material TG not being equal to or higher than a predetermined value may include a preparation period for starting or stopping the operation of the light source apparatus 3. The control unit 300 may displace the shaft portion 120 in the second displacement direction so that the distance between the shield 700 and the target holding unit 110 during the preparation period for starting or stopping the operation of the light source apparatus 3 exceeds the distance during normal operation of the light source apparatus 3. In this case, the control unit 300 may rotate the target holding unit 110 even during the preparation period for starting or stopping the operation of the light source apparatus 3.

The control unit 300 may displace the shaft portion 120 in the second displacement direction so that the distance between the shield 700 and the target holding unit 110 in a case where the target material TG is continuously irradiated with the excitation light LR becomes shorter than the distance between the shield 700 and the target holding unit 110 in a case where the target material TG is not continuously irradiated with the excitation light LR. Accordingly, scattering of the target material TG to outside of the target holding unit 110 can be suppressed, and since an effect of a variation of the surface position when a return current of the debris occurs can be reduced, the operation of the light source apparatus 3 can be stabilized. Note that the case where the target material TG is not continuously irradiated with the excitation light LR includes a case where irradiation of the target material TG with the excitation light LR is stopped.

Next, a control method of the light source apparatus 3 according to the present embodiment will be described with reference to FIG. 6. In the present embodiment, step S15 may be omitted. In the present embodiment, in step S20, the control unit 300 may displace the shaft portion 120 in the second displacement direction by controlling the second magnetic force generating unit 212 so that the distance between the shield 700 and the target holding unit 110 (at least one of distance D1 and distance D2) equals a predetermined target amount. In addition, in step S20, the control unit 300 may displace the shaft portion 120 in the second displacement direction so that at least one of the distances D1 and D2 increases when the fulfillment of predetermined conditions is detected. Specifically, in step S20, the control unit 300 may displace the shaft portion 120 in the second displacement direction so that at least one of the distances D1 and D2 is changed to a greater target amount and the distance between the shield 700 and the target holding unit 110 equals the changed target amount when the fulfillment of predetermined conditions is detected. In addition, in step S20, the control unit 300 may displace the shaft portion 120 in the second displacement direction so that the distance between the shield 700 and the target holding unit 110 in a case where the target material TG is continuously irradiated with the excitation light LR becomes shorter than the distance between the shield 700 and the target holding unit 110 in a case where the target material TG is not continuously irradiated with the excitation light LR.

Next, an advantageous effect of the present embodiment will be described. The light source apparatus 3 according to the present embodiment can displace the shaft portion 120 by controlling the magnetic force generating unit 210 so that the distance between the shield 700 and the target holding unit 110 equals a predetermined target amount. In this manner, since the present embodiment enables the shaft portion 120 to be readily positioned in an up-down direction, a clearance between the shield 700 and the target holding unit 110 can be readily controlled and a stable operation of the light source apparatus 3 can be realized.

### Fourth Embodiment

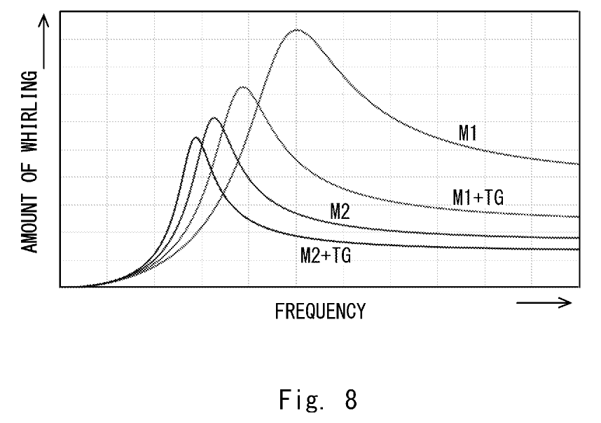

Next, the light source apparatus 3 will be described as a fourth embodiment. FIG. 8 is a graph illustrating an amount of whirling from the rotational axis R when the rotary body 100 rotates around the rotational axis R in the light source apparatus 3 according to the fourth embodiment, in which the horizontal axis indicates a frequency of rotation of the rotary body 100 and the vertical axis indicates the amount of whirling. The horizontal axis and the vertical axis respectively increase in arrow directions.

FIG. 8 shows, when a mass M of the rotary body 100 is a mass M1 and a mass M2, a case where the target material TG is present (M1 + TG and M2 + TG) and a case where the target material TG is absent (M1 and M2), respectively. A relationship among the four masses, namely, the mass M1, the mass M1 + TG, the mass M2, and the mass M2 + TG is expressed as mass M2 + TG > mass M2 > mass M1 + TG > mass M1.

As shown in FIG. 8, the respective masses (mass M1, mass M1 + TG, mass M2, and mass M2 + TG) all have a frequency at which the amount of whirling peaks when the frequency is changed. A velocity (angular velocity) derived from the frequency at which the amount of whirling peaks is called a critical velocity (critical angular velocity) and is represented by ωn = √(k/M), where k denotes a spring constant which can also be considered an axial stiffness coefficient in a physical system model where an object rotates about an elastic axis.

The greater the mass M, the lower the critical velocity ωn. In addition, when the frequency exceeds the critical velocity ωn, the greater the mass M, the smaller the amount of whirling. When the target material TG that is molten metal or the like is present, the critical velocity ωn decreases and the amount of whirling when the frequency exceeds the critical velocity ωn also decreases. This is conceivably due to a balancing effect of liquid.

In the present embodiment, the rotary body 100 and the shaft portion 120 have a mass M and a spring constant k such that the critical angular velocity ωn when the rotary body 100 rotates is equal to or lower than 85% of a target rotational angular velocity ω0, where the target rotational angular velocity ω0 is a target angular velocity at which the rotary body 100 is to be rotated and is an angular velocity that corresponds to the target rotational speed described earlier. As an example, the critical angular velocity ωn when the rotary body 100 rotates may be ensured to be equal to or lower than 85% of the target rotational angular velocity ω0 by at least one of: (1) sufficiently increasing the mass M; and (2) sufficiently reducing the spring constant k by narrowing the shaft diameter by tapering the shaft portion 120 on the side of the bottom portion 112 of the rotary body 100.

The mass M of the rotary body 100 may be a mass in a state where the target material TG is not fed to the rotary body 100. The mass M of the rotary body 100 may be a mass to which is added a mass of the target material TG in a state where the target material TG is fed in any of: an amount smaller than a predetermined target amount; a same amount as the predetermined target amount; and an amount equal to or larger than the predetermined target amount. Among these masses, by setting the mass M of the rotary body 100 as a mass of the rotary body 100 in a state where the target material TG has not been fed, a total mass of the rotary body 100 to which the target material TG has been fed from this state increases by the mass of the target material TG. A critical velocity that maximizes the amount of whirling in this case is an angular velocity that is smaller than the critical angular velocity ωn = √(k/M) in a state where the target material TG has not been fed, meaning that the critical angular velocity ωn will further separate from the target rotational angular velocity ω0, which may be preferable.

### Fifth Embodiment

Next, an optical apparatus including a light source apparatus will be described as a fifth embodiment. Hereinafter, a description will be given using an inspection apparatus as an example of the optical apparatus.

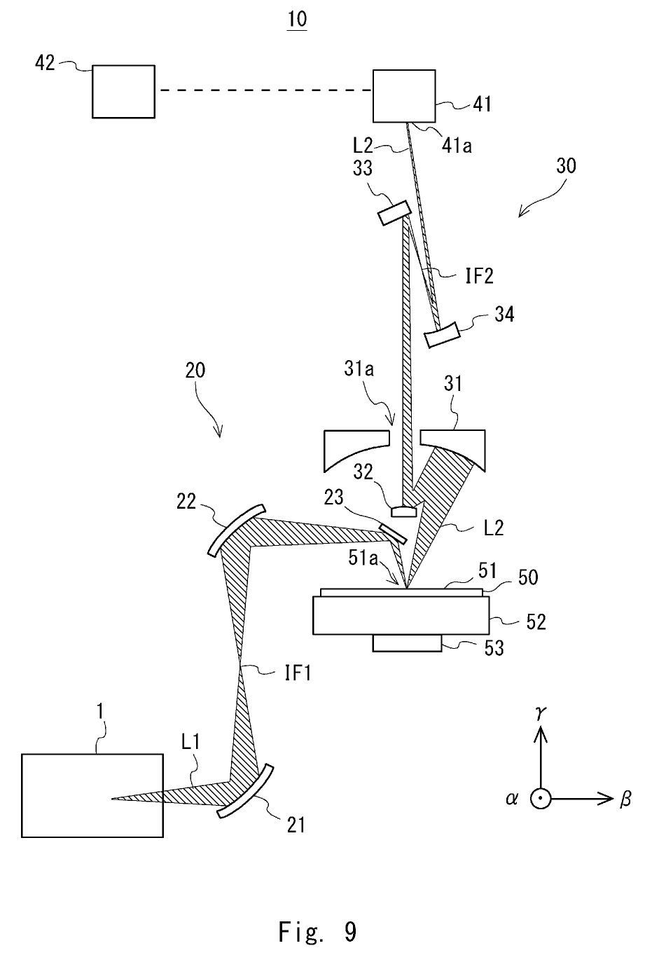

FIG. 9 is a configuration diagram illustrating an inspection apparatus 10 including the light source apparatus 1 according to the fifth embodiment. As shown in FIG. 9, the inspection apparatus 10 includes an illuminating optical system 20, an inspecting optical system 30, a detector 41, and a processing unit 42. Note that the inspection apparatus 10 may further include the light source apparatus 1. The inspection apparatus 10 is an apparatus that uses light LE generated by the light source apparatus 1 as illumination light L1 to inspect a defect or the like of an object 50. For example, the object 50 is an EUV mask. Note that the object 50 is not limited to an EUV mask and may be a semiconductor substrate or the like.

The illuminating optical system 20 includes an ellipsoidal mirror 21, an ellipsoidal mirror 22, and a drop-in mirror 23. The inspecting optical system 30 includes a holed concave mirror 31, a convex mirror 32, a plane mirror 33, and a concave mirror 34. The holed concave mirror 31 and the convex mirror 32 constitute a Schwarzschild magnifying optical system.

The light source apparatus 1 generates the illumination light L1 from the extracted light LE. For example, the illumination light L1 includes EUV light LE of a same wavelength of 13.5 nm as an exposure wavelength of the EUV mask being the object 50. Note that the illumination light L1 may include light other than EUV light. The illumination light L1 having been extracted from the light source apparatus 1 is reflected by the ellipsoidal mirror 21. The illumination light L1 reflected by the ellipsoidal mirror 21 travels while being condensed and is focused on a convergence point IF1. Therefore, the ellipsoidal mirror 21 reflects the illumination light L1 having been generated from the light source apparatus 1 as convergent light. The convergence point IF1 is a position conjugate to an upper surface 51 of the object 50 that is an EUV mask or the like and a detecting surface 41a of the detector 41.

After passing the convergence point IF1, the illumination light L1 travels while spreading and is incident on a reflective mirror such as the ellipsoidal mirror 22. Therefore, the illumination light L1 reflected by the ellipsoidal mirror 21 is incident via the convergence point IF1 on the ellipsoidal mirror 22 as divergent light. The illumination light L1 incident on the ellipsoidal mirror 22 is reflected by the ellipsoidal mirror 22, travels while being condensed, and is incident on the drop-in mirror 23. Therefore, the ellipsoidal mirror 22 reflects the incident illumination light L1 as convergent light. In addition, the ellipsoidal mirror 22 causes the illumination light L1 to be incident on the drop-in mirror 23. The drop-in mirror 23 is arranged directly upward the EUV mask. The illumination light L1 incident on and reflected by the drop-in mirror 23 is incident on the object 50. Therefore, the drop-in mirror 23 causes the illumination light L1 reflected by the ellipsoidal mirror 22 to be incident on the object 50 by reflecting the illumination light L1 toward the object 50.

The ellipsoidal mirror 22 focuses the illumination light L1 on the object 50. The illuminating optical system 20 is installed such that an image of the light source apparatus 1 is formed on the upper surface 51 of the object 50 when the illumination light L1 illuminates the object 50. Therefore, the illuminating optical system 20 constitutes a critical illumination. In this manner, the illuminating optical system 20 illuminates the object 50 that is an EUV mask or the like using the critical illumination due to the illumination light L1 generated by the light source apparatus.

The object 50 is arranged on a stage 52. Here, let a plane parallel to the upper surface 51 of the object 50 be an αβ plane and a direction perpendicular to the αβ plane be a γ-axis direction. The illumination light L1 is incident on the object 50 in a direction inclined with respect to the γ-axis direction. In other words, the illumination light L1 is obliquely incident and illuminates the object 50.

The stage 52 is a three-dimensionally driven stage that includes a drive unit 53. The drive unit 53 can cause a desired region of the object 50 to be illuminated by moving the stage 52 within the αβ plane. Furthermore, the drive unit 53 can perform focus adjustment by moving the stage 52 in the γ-axis direction.

The illumination light L1 from the light source apparatus 1 illuminates an inspection region of the object 50. The inspection region to be illuminated by the illumination light L1 is, for example, a 0.5 mm-square. Note that the inspection region is not limited to a 0.5 mm-square. The illumination light L1 is incident on the object 50 in a direction inclined with respect to the γ-axis direction. Light from the object 50 that is illuminated by the illumination light L1 is incident on the holed concave mirror 31. Hereinafter, the light from the object 50 that is illuminated by the illumination light L1 will be described as reflected light L2. Light incident on the holed concave mirror 31 from the object 50 is not limited to the reflected light L2 and may include diffracted light or the like. The reflected light L2 reflected by the object 50 is incident on the holed concave mirror 31. A hole 31a is provided at a center of the holed concave mirror 31. The holed concave mirror 31 focuses the reflected light L2 from the object 50 and reflects the focused reflected light L2 as convergent light.

The reflected light L2 reflected by the holed concave mirror 31 is incident on the convex mirror 32. The convex mirror 32 reflects, toward the hole 31a of the holed concave mirror 31, the reflected light L2 reflected by the holed concave mirror 31. The reflected light L2 having passed through the hole 31a is incident on the plane mirror 33. The plane mirror 33 causes the reflected light L2 reflected by the convex mirror 32 to be incident as convergent light through the hole 31a of the holed concave mirror 31. The reflected light L2 incident on the plane mirror 33 is reflected by the plane mirror 33. The reflected light L2 reflected by the plane mirror 33 travels while being condensed and is focused on a convergence point IF2. Therefore, the plane mirror 33 reflects the incident reflected light L2 as convergent light. The convergence point IF2 may sometimes be referred to as an aperture diaphragm. The convergence point IF2 is a position conjugate to the upper surface 51 of the object 50 and the detecting surface 41a of the detector 41.

After passing the convergence point IF2, the reflected light L2 travels while spreading and is incident on the concave mirror 34. Therefore, the reflected light L2 reflected by the plane mirror 33 as convergent light is incident via the convergence point IF2 on the concave mirror 34 as divergent light. The concave mirror 34 reflects the incident reflected light L2 as convergent light toward the detector 41. The reflected light L2 reflected by the concave mirror 34 is detected by the detector 41. In this manner, the inspecting optical system 30 inspects the object 50 that is an inspection object with the illumination light L1 extracted from the output optical system 600 of the light source apparatus 1. In other words, the inspecting optical system 30 focuses the reflected light L2 from the object 50 illuminated by the illumination light L1 and guides the focused reflected light L2 to the detector 41.

The detector 41 may include a TDI (Time Delay Integration) sensor. The detector 41 receives light from the object 50 illuminated by the illumination light L1. A region on the object 50 that is detected by the detector 41 is referred to as a visual field region 51a. The detector 41 receives the reflected light L2 from the visual field region 51a illuminated by the illumination light L1. The visual field region 51a may be included in the inspection region illuminated by the illumination light L1. The detector 41 acquires image data of the object 50 that is an EUV mask or the like. When the detector 41 includes a TDI sensor, the detector 41 includes a plurality of imaging elements arranged in a line-shape in one direction. For example, the imaging elements are CCDs (Charge Coupled Devices). Note that the imaging elements are not limited to CCDs.

Image data of the object 50 acquired by the detector 41 is outputted to the processing unit 42 and processed by the processing unit 42. For example, the processing unit 42 may be an information processing apparatus such as a server apparatus or a personal computer.

The reflected light L2 includes information such as a defect or the like of the object 50. Regular reflected light of the illumination light L1 incident on the object 50 in a direction inclined with respect to the Z-axis direction is detected by the inspecting optical system 30. When a defect is present in the object 50, the defect is observed as a dark image. Such an observation method is referred to as bright-field observation. Note that the inspection apparatus 10 may cause the illumination light L1 to be incident on the object 50 in the Z-axis direction and have the inspecting optical system 30 detect the illumination light L1. When a defect is present in the object 50, the defect is observed as a bright image. Such an observation method is referred to as dark-field observation.

As described above, the inspection apparatus 10 according to the present embodiment includes the light source apparatus 1 described earlier and the inspecting optical system 30 that inspects an inspection object with light LE extracted from the output optical system 600. An inspection method using the inspection apparatus 10 includes a step of inspecting the inspection object with the light LE extracted according to the control method of the light source apparatus 1 described earlier. Note that while the inspection apparatus 10 has been described as an optical apparatus, the optical apparatus may be an exposure apparatus. For example, the exposure apparatus includes the light source apparatus 1 described earlier and an exposure optical system that exposes an exposure object with light LE extracted from the output optical system 600. An exposure method using the exposure apparatus includes a step of exposing the exposure object with the light LE extracted according to the control method of the light source apparatus 1 described earlier.

Next, an advantageous effect of the present embodiment will be described. An optical apparatus including the inspection apparatus 10 according to the present embodiment includes the light source apparatus 1. Accordingly, stability of the illumination light L1 that illuminates the object 50 can be improved. Other configurations and advantageous effects are included in the descriptions of the first to fourth embodiments provided earlier.

While embodiments of the present disclosure have been described above, the present disclosure includes appropriate modifications that do not impair its purpose and advantages and, further, the present disclosure is not limited by the above embodiments. In addition, respective configurations of the first to fifth embodiments may be appropriately combined. Furthermore, the light source apparatuses 1 to 3 that include the control unit 300 configured as follows also fall within the technical scope of embodiments.

The control unit 300 includes a processor, a memory, and a storage apparatus as an unillustrated configuration. The storage apparatus stores a program that causes a computer to execute each processing step of the control method of the light source apparatus according to each embodiment. The processor causes the program to be loaded onto the memory from the storage apparatus and executes the program. Accordingly, the processor realizes each function of the control unit 300. Note that each of the constituent elements of the control unit 300 may be realized by dedicated hardware. In addition, a part of or all of each constituent element may be realized by a general-purpose or dedicated circuit, a processor or the like, or a combination thereof. The constituent elements may be constituted of a single chip or a plurality of chips connected to each other via a bus. A part of or all of each constituent element may be realized by a combination of the circuit or the like and a program described above. In addition, a CPU (Central Processing Unit), a GPU (Graphics Processing Unit), or the like may be used as the processor. In the example described above, the program includes a set of instructions (or software code) that, when loaded into a computer, causes the computer to perform one or more functions described in the embodiments. The program may be stored on a non-transitory computer-readable medium or a physical storage medium. By way of example and not limitation, the computer-readable medium or the physical storage medium includes: a random-access memory (RAM), a read-only memory (ROM), a flash memory, a solid-state drive (SSD), or other memory technology; a CD-ROM, a digital versatile disc (DVD), a Blu-ray (registered trademark) disc, or other optical disc storages; and a magnetic cassette, a magnetic tape, a magnetic disk storage, or other magnetic storage devices. The program may be transmitted on a transitory computer-readable medium or a communication medium. By way of example and not limitation, the transitory computer-readable medium or the communication medium includes signals propagated in electrical, optical, acoustic, or other formats.

The program can be stored and provided to a computer using any type of non-transitory computer readable media. Non-transitory computer readable media include any type of tangible storage media. Examples of non-transitory computer readable media include magnetic storage media (such as floppy disks, magnetic tapes, hard disk drives, etc.), optical magnetic storage media (e.g. magneto-optical disks), CD-ROM (compact disc read only memory), CD-R (compact disc recordable), CD-R/W (compact disc rewritable), and semiconductor memories (such as mask ROM, PROM (programmable ROM), EPROM (erasable PROM), flash ROM, RAM (random access memory), etc.). The program may be provided to a computer using any type of transitory computer readable media. Examples of transitory computer readable media include electric signals, optical signals, and electromagnetic waves. Transitory computer readable media can provide the program to a computer via a wired communication line (e.g. electric wires, and optical fibers) or a wireless communication line.

The first to fifth embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A light source apparatus, comprising:
a rotary body which includes a target holding unit configured to hold a target material that serves as a plasma source configured to generate plasma and a shaft portion connected to the target holding unit and which rotates around a rotational axis that passes through the shaft portion;
a shaft support portion which includes a magnetic force generating unit configured to apply a magnetic force to the shaft portion and which is configured to support the shaft portion; and
a control unit configured to control the magnetic force generating unit,
wherein the shaft support portion is configured to rotatably support the shaft portion in a state where the shaft portion is levitated by the magnetic force via the magnetic force generating unit, and
wherein the control unit is configured to displace the shaft portion by controlling the magnetic force generating unit.

2. The light source apparatus according to claim 1, wherein:
the magnetic force generating unit includes a first magnetic force generating unit configured to apply the magnetic force to the shaft portion, and
the control unit is configured to displace the shaft portion in a first displacement direction including a component perpendicular to the rotational axis by controlling the first magnetic force generating unit.

3. The light source apparatus according to claim 1, wherein:
the rotary body further includes a disk portion which is connected to the shaft portion and which has a diameter that differs from a diameter of the shaft portion,
the magnetic force generating unit includes a second magnetic force generating unit configured to apply the magnetic force to the disk portion, and
the control unit is configured to displace the shaft portion in a second displacement direction including a component parallel to the rotational axis by controlling the second magnetic force generating unit.

4. The light source apparatus according to claim 2, wherein when the target material generates plasma, the control unit is configured to:
rotate the rotary body at a target rotational speed, and
displace the shaft portion in the first displacement direction in a state where the shaft portion is rotating at the target rotational speed by controlling the first magnetic force generating unit.

5. The light source apparatus according to claim 2, further comprising an acquiring unit configured to acquire a state of a holding surface for holding the target material in the target holding unit,
wherein the control unit is configured to displace the shaft portion in the first displacement direction based on an acquisition result of the state of the holding surface by the acquiring unit.

6. The light source apparatus according to claim 5, wherein the state of the holding surface includes at least one of: an amount of the target material held by the holding surface; a surface position of the target material; a surface roughness of the target material; and a surface roughness of the holding surface.

7. The light source apparatus according to claim 5, further comprising:
an input optical system which has a first focusing point that is a focusing point on a side of the target material of a first optical member configured to focus excitation light onto the target material and which is configured to irradiate the target material with the excitation light; and
an output optical system which has a second focusing point that is a focusing point on a side of the target material of a second optical member configured to focus light generated from the plasma source and which is configured to extract the light generated from the plasma source,
wherein the acquiring unit is configured to acquire a displacement of a surface position of the target material, and
wherein the control unit is configured to displace, when the surface position is displaced, the shaft portion so that relative positions of the surface position of the target material at an irradiation position of the excitation light and at least one of the first focusing point and the second focusing point become approximately constant before and after the displacement of the surface position.

8. The light source apparatus according to claim 3, wherein the target holding unit includes:
a cylindrical portion, and
a bottom portion configured to close an end of the cylindrical portion,
wherein the light source apparatus further includes a shield configured to close the other end of the cylindrical portion, and
wherein the control unit is configured to displace the shaft portion in the second displacement direction by controlling the second magnetic force generating unit so that a distance between the shield and the cylindrical portion equals a predetermined target amount.

9. The light source apparatus according to claim 8, wherein:
the control unit is configured to displace the shaft portion in the second displacement direction so that the distance increases when the control unit detects that predetermined conditions are fulfilled, and
the predetermined conditions include at least one of detection of a vibration of the rotary body that is greater than a predetermined vibration and detection of a rotational speed of the rotary body that is lower than a predetermined rotational speed.

10. The light source apparatus according to claim 7, wherein the control unit is configured to acquire the surface position of the target material at the irradiation position based on a state of the holding surface which is acquired by the acquiring unit and which corresponds to a position that differs from the irradiation position.

11. The light source apparatus according to claim 7, wherein the control unit is configured to displace the shaft portion in the first displacement direction when the surface position is displaced in a direction of increase of the target material by a predetermined amount.

12. A control method of a light source apparatus,
the light source apparatus including:
a rotary body which includes a target holding unit that holds a target material that serves as a plasma source that generates plasma and a shaft portion connected to the target holding unit and which rotates around a rotational axis that passes through the shaft portion;
a shaft support portion which includes a magnetic force generating unit that applies a magnetic force to the shaft portion and which supports the shaft portion; and
a control unit which controls the magnetic force generating unit,
the control method comprising the steps of:
the shaft support portion rotatably supporting the shaft portion in a state where the shaft portion is levitated by the magnetic force via the magnetic force generating unit; and
the control unit displacing the shaft portion by controlling the magnetic force generating unit.

13. The control method of a light source apparatus according to claim 12, wherein:
the magnetic force generating unit includes a first magnetic force generating unit that applies the magnetic force to the shaft portion, and
in the step of displacing the shaft portion, the control unit displaces the shaft portion in a first displacement direction including a component perpendicular to the rotational axis by controlling the first magnetic force generating unit.

14. The control method of a light source apparatus according to claim 12, wherein:
the rotary body further includes a disk portion which is connected to the shaft portion and which has a diameter that differs from a diameter of the shaft portion,
the magnetic force generating unit includes a second magnetic force generating unit that applies the magnetic force to the disk portion, and
in the step of displacing the shaft portion, the control unit displaces the shaft portion in a second displacement direction including a component parallel to the rotational axis by controlling the second magnetic force generating unit.

15. The control method of a light source apparatus according to claim 13, wherein:
in the step of rotatably supporting the shaft portion, when the target material generates plasma, the control unit rotates the rotary body at a target rotational speed, and
in the step of displacing the shaft portion, the control unit displaces the shaft portion in the first displacement direction in a state where the shaft portion is rotating at the target rotational speed by controlling the first magnetic force generating unit.

16. The control method of a light source apparatus according to claim 13, further comprising a step of:
causing an acquiring unit to acquire a state of a holding surface for holding the target material in the target holding unit, and
in the step of displacing the shaft portion, the control unit displaces the shaft portion in the first displacement direction based on an acquisition result of the state of the holding surface by the acquiring unit.

17. The control method of a light source apparatus according to claim 16, wherein the state of the holding surface includes at least one of: an amount of the target material held by the holding surface; a surface position of the target material; a surface roughness of the target material; and a surface roughness of the holding surface.

18. The control method of a light source apparatus according to claim 16, wherein the light source apparatus further includes:
an input optical system which has a first focusing point that is a focusing point on a side of the target material of a first optical member that focuses excitation light onto the target material and which irradiates the target material with the excitation light; and
an output optical system which has a second focusing point that is a focusing point on a side of the target material of a second optical member that focuses light generated from the plasma source and which extracts the light generated from the plasma source,
wherein, in the step of causing the acquiring unit to acquire a state of the holding surface, the acquiring unit acquires a displacement of a surface position of the target material, and
wherein, in the step of displacing the shaft portion, the control unit displaces, when the surface position is displaced, the shaft portion so that relative positions of the surface position of the target material at an irradiation position of the excitation light and at least one of the first focusing point and the second focusing point become approximately constant before and after the displacement of the surface position.

19. The control method of a light source apparatus according to claim 14, wherein the target holding unit includes:
a cylindrical portion, and
a bottom portion that closes an end of the cylindrical portion,
wherein the light source apparatus further includes a shield that closes the other end of the cylindrical portion,
wherein, in at least one of the step of rotatably supporting the shaft portion and the step of displacing the shaft portion, the control unit displaces the shaft portion in the second displacement direction by controlling the second magnetic force generating unit so that a distance between the shield and the cylindrical portion equals a predetermined target amount.

20. The control method of a light source apparatus according to claim 19, wherein:
in at least one of the step of rotatably supporting the shaft portion and the step of displacing the shaft portion, the control unit displaces the shaft portion in the second displacement direction so that the distance increases when the control unit detects that predetermined conditions are fulfilled, and
the predetermined conditions include at least one of detection of a vibration of the rotary body that is greater than a predetermined vibration and detection of a rotational speed of the rotary body that is lower than a predetermined rotational speed.

21. The control method of a light source apparatus according to claim 18, wherein:
in the step of causing the acquiring unit to acquire a state of the holding surface, the control unit acquires the surface position of the target material at the irradiation position based on a state of the holding surface which is acquired by the acquiring unit and which corresponds to a position that differs from the irradiation position.

22. The control method of a light source apparatus according to claim 18, wherein:
in the step of displacing the shaft portion, the control unit displaces the shaft portion in the first displacement direction when the surface position is displaced in a direction of increase of the target material by a predetermined amount.
